(19) United States
(12) Patent Application Publication
(10) Pub. No.: US 2016/0197149 A1
(43) Pub. Date: Jul. 7, 2016

(54) SILICON CARBIDE SEMICONDUCTOR DEVICE AND METHOD FOR MANUFACTURING SAME

(71) Applicant: Sumitomo Electric Industries, Ltd., Osaka-shi, Osaka (JP)

(72) Inventor: Mitsuhiko SAKAI, Osaka-shi (JP)

(21) Appl. No.: 14/913,200

(22) PCT Filed: Jul. 4, 2014
(86) PCT No.: PCT/JP2014/067868

§ 371 Date: Feb. 19, 2016

(30) Foreign Application Priority Data
Aug. 20, 2013 (JP) 2013-170561

(51) Int. Cl. H01L 29/16; H01L 21/306; H01L 29/04; H01L 29/872; H01L 29/66; H01L 29/739; H01L 29/78; H01L 21/04; H01L 29/45

(52) U.S. Cl. CPC H01L 29/1608; H01L 21/0485; H01L 21/0475; H01L 21/30625; H01L 29/04; H01L 29/45; H01L 29/6606; H01L 29/66068; H01L 29/7395; H01L 29/7802; H01L 29/872

(57) ABSTRACT

A first electrode being in contact with the first main surface of the silicon carbide semiconductor substrate and in ohmic junction with the silicon carbide semiconductor substrate is formed. At least a portion of the silicon carbide semiconductor substrate on a side of the second main surface is removed. A second electrode in contact with the second main surface of the silicon carbide semiconductor substrate exposed by removing at least a portion of the silicon carbide semiconductor substrate and in ohmic junction with the silicon carbide semiconductor substrate is formed. A metal layer being in electrical contact with a fourth main surface of the second electrode is formed. A thickness of the metal layer is greater than a thickness of the silicon carbide semiconductor substrate after the removal of at least a portion of the silicon carbide semiconductor substrate.

### TECHNICAL FIELD

The present invention relates to a silicon carbide semiconductor device and a method for manufacturing the same, and particularly to a silicon carbide semiconductor device capable of reducing the on-resistance and a method for manufacturing the same.

### BACKGROUND ART

In recent years, in order to achieve high breakdown voltage, low loss, use under a high temperature environment, and the like in a semiconductor device such as a MOSFET (Metal Oxide Semiconductor Field Effect Transistor), silicon carbide has begun to be adopted as a material constituting a semiconductor device. Silicon carbide is a wide bandgap semiconductor having a band gap larger than that of silicon, which has been conventionally widely used as a material constituting a semiconductor device. Therefore, by adopting silicon carbide as a material constituting a semiconductor device, the semiconductor device can achieve a high breakdown voltage, reduced on-resistance, and the like. Moreover, a semiconductor device adopting silicon carbide as its material also has an advantage that its characteristics are less likely to be deteriorated when it is used under the high temperature environment, when compared with a semiconductor device adopting silicon as its material.

A semiconductor device such as a MOSFET in some cases has a semiconductor substrate, an ohmic electrode formed on a backside surface of the semiconductor substrate, and a backside electrode in contact with the ohmic electrode. For example, Japanese Patent Laying-Open No. 2011-35322 (PTD 1) discloses a semiconductor device having a recess formed in a portion of a backside surface of a silicon carbide substrate, and having a backside electrode formed so as to fill the recess.

### CITATION LIST

### Patent Document

PTD 1: Japanese Patent Laying-Open No. 2011-35322

### SUMMARY OF INVENTION

### Technical Problem

However, according to the above-described semiconductor device, it was difficult to sufficiently reduce the on-resistance of the silicon carbide semiconductor device.

The present invention was made in view of the above-described problem, and its object is to provide a silicon carbide semiconductor device capable of reducing on-resistance and a method for manufacturing the same.

### Solution to Problem

A method for manufacturing a silicon carbide semiconductor device in accordance with the present invention includes the following steps. A silicon carbide semiconductor substrate having a first main surface and a second main surface opposite to the first main surface is prepared. The silicon carbide semiconductor substrate includes a silicon carbide single-crystal substrate constituting the second main surface and a silicon carbide epitaxial layer being provided in contact with the silicon carbide single-crystal substrate and constituting the first main surface. A first electrode being in contact with the first main surface of the silicon carbide semiconductor substrate and in ohmic junction with the silicon carbide semiconductor substrate is formed. At least a portion of the silicon carbide semiconductor substrate on a side of the second main surface is removed. A second electrode having a third main surface, which is in contact with the second main surface of the silicon carbide semiconductor substrate exposed by the removal of at least a portion of the silicon carbide semiconductor substrate on a side of the second main surface, and a fourth main surface opposite to the third main surface, and in ohmic junction with the silicon carbide semiconductor substrate is formed. A metal layer being in electrical contact with the fourth main surface of the second electrode is formed. A thickness of the metal layer is greater than a thickness of the silicon carbide semiconductor substrate after the removal of at least a portion of the silicon carbide semiconductor substrate on a side of the second main surface.

A silicon carbide semiconductor device in accordance with the present invention includes a silicon carbide semiconductor substrate, a first electrode, a second electrode, and a metal layer. The silicon carbide semiconductor substrate has a first main surface and a second main surface opposite to the first main surface. The silicon carbide semiconductor substrate includes a silicon carbide epitaxial layer constituting the first main surface. The first electrode is in contact with the first main surface of the silicon carbide semiconductor substrate and in ohmic junction with silicon carbide semiconductor substrate. The second electrode has a third main surface in contact with the second main surface of the silicon carbide semiconductor substrate and a fourth main surface opposite to the third main surface and is in ohmic junction with the silicon carbide semiconductor substrate. The metal layer is in electrical contact with the fourth main surface of the second electrode. A thickness of the metal layer is greater than a thickness of the silicon carbide semiconductor substrate.

### Advantageous Effects of Invention

According to the present invention, a silicon carbide semiconductor device capable of reducing on-resistance and a method for manufacturing the same can be provided.

### BRIEF DESCRIPTION OF DRAWINGS

FIG. 1 is a schematic cross sectional view schematically showing a configuration of a silicon carbide semiconductor device in accordance with a first embodiment of the present invention.

FIG. 2 is a flowchart schematically showing a method for manufacturing the silicon carbide semiconductor device in accordance with the first embodiment of the present invention.

FIG. 3 is a schematic cross sectional view schematically showing a first step of the silicon carbide semiconductor device in accordance with the first embodiment of the present invention.

FIG. 4 is a schematic cross sectional view schematically showing a second step of the silicon carbide semiconductor device in accordance with the first embodiment of the present invention.

FIG. 5 is a schematic cross sectional view schematically showing a third step of the silicon carbide semiconductor device in accordance with the first embodiment of the present invention.

FIG. 6 is a schematic cross sectional view schematically showing a fourth step of the silicon carbide semiconductor device in accordance with the first embodiment of the present invention.

FIG. 7 is a schematic cross sectional view schematically showing a fifth step of the silicon carbide semiconductor device in accordance with the first embodiment of the present invention.

FIG. 8 is a schematic plan view schematically showing the fifth step of the silicon carbide semiconductor device in accordance with the first embodiment of the present invention.

FIG. 9 is a schematic cross sectional view schematically showing a sixth step of the silicon carbide semiconductor device in accordance with the first embodiment of the present invention.

FIG. 10 is a schematic cross sectional view schematically showing a seventh step of the silicon carbide semiconductor device in accordance with the first embodiment of the present invention.

FIG. 11 is a schematic cross sectional view schematically showing an eighth step of the silicon carbide semiconductor device in accordance with the first embodiment of the present invention.

FIG. 12 is a schematic cross sectional view schematically showing a ninth step of the silicon carbide semiconductor device in accordance with the first embodiment of the present invention.

FIG. 13 is a schematic cross sectional view schematically showing a configuration of a silicon carbide semiconductor device in accordance with a second embodiment of the present invention.

FIG. 14 is a schematic cross sectional view schematically showing a fifth step of the silicon carbide semiconductor device in accordance with the second embodiment of the present invention.

FIG. 15 is a schematic cross sectional view schematically showing a configuration of a silicon carbide semiconductor device in accordance with a third embodiment of the present invention.

FIG. 16 is a schematic cross sectional view schematically showing a fifth step of the silicon carbide semiconductor device in accordance with the third embodiment of the present invention.

FIG. 17 is a schematic cross sectional view schematically showing a configuration of a silicon carbide semiconductor device in accordance with a fourth embodiment of the present invention.

FIG. 18 is a schematic cross sectional view schematically showing a fifth step of the silicon carbide semiconductor device in accordance with the fourth embodiment of the present invention.

### DESCRIPTION OF EMBODIMENTS

Hereinafter, embodiments of the present invention will be described with reference to the drawings. It should be noted that, in the below-mentioned drawings, the same or corresponding portions are given the same reference characters and are not described repeatedly. Further, regarding crystallographic indications in the present specification, an individual orientation is represented by [ ], a group orientation is represented by < >, an individual plane is represented by ( ) and a group plane is represented by { }. In addition, a negative crystallographic index is normally expressed by putting “−” (bar) above a numeral, but is expressed by putting the negative sign before the numeral in the present specification. Moreover, as to description of angles, the system having an omnidirection angle of 360 degrees is used.

### Description of Embodiments of the Present Invention

(1) A method for manufacturing a silicon carbide semiconductor device 1 in accordance with an embodiment includes the following steps. A silicon carbide semiconductor substrate 10 having a first main surface 10a and a second main surface 10b opposite to first main surface 10a is prepared. Silicon carbide semiconductor substrate 10 includes a silicon carbide single-crystal substrate 11 constituting second main surface 10b and a silicon carbide epitaxial layer 32 being provided in contact with silicon carbide single-crystal substrate 11 and constituting first main surface 10a. A first electrode 16 being in contact with first main surface 10a of silicon carbide semiconductor substrate 10 and in ohmic junction with silicon carbide semiconductor substrate 10 is formed. At least a portion of silicon carbide semiconductor substrate 10 on a side of second main surface 10b is removed. A second electrode 20 having a third main surface 20a, which is in contact with second main surface 10b of silicon carbide semiconductor substrate 10 exposed by the step of removing at least a portion of silicon carbide semiconductor substrate 10 on a side of second main surface 10b, and a fourth main surface 20b opposite to third main surface 20a, and in ohmic junction with silicon carbide semiconductor substrate 10 is formed. A metal layer 22 being in electrical contact with fourth main surface 20b of second electrode 20 is formed. A thickness of metal layer 22 is greater than a thickness of silicon carbide semiconductor substrate 10 after the step of removing at least a portion of silicon carbide semiconductor substrate 10 on a side of second main surface 10b.

According to the method for manufacturing silicon carbide semiconductor device 1 in accordance with the embodiment, metal layer 22 being in electrical contact with fourth main surface 20b of second electrode 20 is formed. The thickness of metal layer 22 is greater than the thickness of silicon carbide semiconductor substrate 10 after the step of removing at least a portion of silicon carbide semiconductor substrate 10 on a side of second main surface 10b. Accordingly, on-resistance of silicon carbide semiconductor device 1 can be reduced. Moreover, the rigidity of silicon carbide semiconductor device 1 can be maintained high to the extent that silicon carbide semiconductor device 1 can be self-supported.

(2) In the method for manufacturing silicon carbide semiconductor device 1 in accordance with the above-described item (1), preferably, the step of forming metal layer 22 includes the step of forming metal layer 22 so as to cover an entire surface of fourth main surface 20b of second electrode 20. Accordingly, on-resistance of silicon carbide semiconductor device 1 can be reduced effectively.

(3) In the method for manufacturing silicon carbide semiconductor device 1 in accordance with the above-described item (1) or (2), preferably, the step of removing at least a portion of silicon carbide semiconductor substrate 10 on a side of second main surface 10b includes the step of entirely removing silicon carbide single-crystal substrate 11 so that silicon carbide epitaxial layer 32 is exposed. Accordingly, on-resistance of silicon carbide semiconductor device 1 can be reduced more effectively.

(4) In the method for manufacturing silicon carbide semiconductor device 1 in accordance with the above-described item (1) or (2), preferably, the step of removing at least a portion of silicon carbide semiconductor substrate 10 on a side of second main surface 10b includes the step of forming a recess in second main surface 10b of silicon carbide semiconductor substrate 10. The step of forming metal layer 22 includes the step of forming metal layer 22 which enters the recess and covers second main surface 10b. The method further includes the step of removing a portion of metal layer 22 by chemical machine polishing so that second main surface 10b of silicon carbide semiconductor substrate 10 is exposed after the step of forming metal layer 22. Accordingly, on-resistance of silicon carbide semiconductor device 1 can be reduced effectively.

(5) In the method for manufacturing silicon carbide semiconductor device 1 in accordance with the above-described item (4), preferably, the step of forming a recess in second main surface 10b of silicon carbide semiconductor substrate 10 has the step of forming the recess so that silicon carbide single-crystal substrate 11 remains along a dicing line. Accordingly, dicing of silicon carbide semiconductor substrate 10 becomes easier than the case where metal layer 22 is formed along the dicing line.

(6) In the method for manufacturing silicon carbide semiconductor device 1 in accordance with the above-described items (4) or (5), preferably, the step of forming recess TQ in second main surface 10b of silicon carbide semiconductor substrate 10 has the step of forming recess TQ so that a bottom portion B of recess TQ is located in silicon carbide epitaxial layer 32. Accordingly, on-resistance of silicon carbide semiconductor device 1 can be reduced effectively.

(7) In the method for manufacturing silicon carbide semiconductor device 1 in accordance with any one of the above-described items (1) to (6), preferably, a thickness of the portion removed by the step of removing at least a portion of silicon carbide semiconductor substrate 10 on a side of second main surface 10b is greater than or equal to 250 μm and less than or equal to 500 μm. By setting the thickness of the removed portion to be greater than or equal to 250 μm, on-resistance of silicon carbide semiconductor device 1 can be reduced effectively. By setting the thickness of the removed portion to be less than or equal to 500 μm, the rigidity of silicon carbide semiconductor device 1 can be maintained high to the extent that silicon carbide semiconductor device 1 can be self-supported.

(8) In the method for manufacturing silicon carbide semiconductor device 1 in accordance with any one of the above-described items (1) to (7), preferably, a thickness of metal layer 22 is greater than or equal to 50 μm and less than or equal to 300 μm. By setting the thickness of metal layer 22 to be greater than or equal to 50 μm, the rigidity of silicon carbide semiconductor device 1 can be maintained to the extent that silicon carbide semiconductor device 1 can be self-supported. By setting the thickness of metal layer 22 to be less than or equal to 300 μm, on-resistance of silicon carbide semiconductor device 1 can be reduced effectively.

(9) A silicon carbide semiconductor device 1 in accordance with the embodiments includes a silicon carbide semiconductor substrate 10, a first electrode 16, a second electrode 20, and a metal layer 22. Silicon carbide semiconductor substrate 10 has a first main surface 10a and a second main surface 10b opposite to first main surface 10a. Silicon carbide semiconductor substrate 10 includes a silicon carbide epitaxial layer 32 constituting first main surface 10a. First electrode 16 is in contact with first main surface 10a of silicon carbide semiconductor substrate 10 and in ohmic junction with silicon carbide semiconductor substrate 10. Second electrode 20 has a third main surface 20a in contact with second main surface 10b of silicon carbide semiconductor substrate 10 and a fourth main surface 20b opposite to third main surface 20a and is in ohmic junction with silicon carbide semiconductor substrate 10. Metal layer 22 is in electrical contact with fourth main surface 20b of second electrode 20. A thickness of metal layer 22 is greater than a thickness of silicon carbide semiconductor substrate 10.

According to silicon carbide semiconductor device 1 in accordance with the embodiments, metal layer 22 is in electrical contact with fourth main surface 20b of second electrode 20. The thickness of metal layer 22 is greater than the thickness of silicon carbide semiconductor substrate 10. Accordingly, on-resistance of silicon carbide semiconductor device 1 can be reduced. Moreover, the rigidity of silicon carbide semiconductor device 1 can be maintained high to the extent that silicon carbide semiconductor device 1 can be self-supported.

(10) In silicon carbide semiconductor device 1 in accordance with the above-described item (9), metal layer 22 is provided so as to cover an entire surface of fourth main surface 20b of second electrode 20. Accordingly, on-resistance of silicon carbide semiconductor device 1 can be reduced effectively.

(11) In silicon carbide semiconductor device 1 in accordance with the above-described item (9) or (10), silicon carbide semiconductor substrate 10 includes a silicon carbide single-crystal substrate 11 being in contact with silicon carbide epitaxial layer 32 and constituting second main surface 10b. Accordingly, silicon carbide semiconductor device 1 with a high rigidity can be obtained.

(12) In silicon carbide semiconductor device 1 in accordance with the above-described item (11), preferably, second main surface 10b of silicon carbide semiconductor substrate 10 is provided with a recess having a side wall portion constituted of silicon carbide single-crystal substrate 11. Second electrode 20 and metal layer 22 are provided so as to enter the recess. Accordingly, on-resistance of silicon carbide semiconductor device 1 can be reduced effectively.

(13) In silicon carbide semiconductor device 1 in accordance with the above-described item (12), preferably, the recess is formed so that silicon carbide single-crystal substrate 11 remains in an outer circumferential end portion of silicon carbide semiconductor substrate 10 in a plan view. Accordingly, while maintaining high rigidity of silicon carbide semiconductor device 1, on-resistance of silicon carbide semiconductor device 1 can be reduced effectively.

(14) In silicon carbide semiconductor device 1 in accordance with the above-described item (12) or (13), preferably, a bottom portion of the recess is located in silicon carbide epitaxial layer 32. Accordingly, on-resistance of silicon carbide semiconductor device 1 can be reduced effectively.

(15) In silicon carbide semiconductor device 1 in accordance with any one of the above-described items (9) to (14), preferably, a thickness of metal layer 22 is greater than or equal to 50 μm and less than or equal to 300 μm. By setting the thickness of metal layer 22 to be greater than or equal to 50 μm, the rigidity of silicon carbide semiconductor device 1 can be maintained high to the extent that silicon carbide semiconductor device 1 can be self-supported. By setting the thickness of metal layer 22 to be less than or equal to 300 μm, on-resistance of silicon carbide semiconductor device 1 can be reduced effectively.

(16) In silicon carbide semiconductor device 1 in accordance with any one of the above-described items (9) to (15), preferably, metal layer 22 contains copper. Accordingly, while maintaining high rigidity of silicon carbide semiconductor device 1, on-resistance of silicon carbide semiconductor device 1 can be reduced effectively.

### Details of the Embodiments of the Present Invention

### First Embodiment

Firstly, a configuration of a MOSFET 1 as one example of a silicon carbide semiconductor device 1 in accordance with the first embodiment of the present invention will be described.

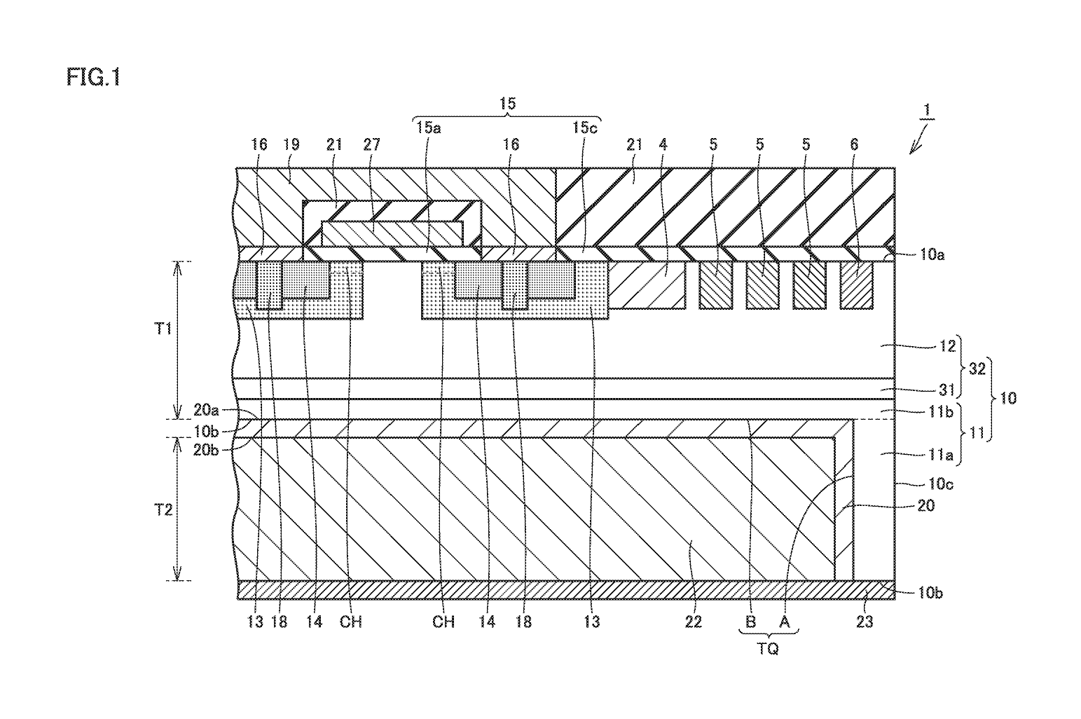

Referring to FIG. 1, MOSFET 1 in accordance with the first embodiment mainly has a silicon carbide semiconductor substrate 10, a gate insulating film 15a, a gate electrode 27, a source electrode 16, an interlayer insulating film 21, a source interconnection 19, a drain electrode 20, a metal layer 22, a backside surface protecting electrode 23, and a breakdown voltage holding portion 15c.

Silicon carbide semiconductor substrate 10 has a first main surface 10a and a second main surface 10b opposite to first main surface 10a. First main surface 10a of silicon carbide semiconductor substrate 10 is, for example, a plane which is offset from a (0001) plane by about less than or equal to 8°. Silicon carbide semiconductor substrate 10 includes a silicon carbide single-crystal substrate 11 and a silicon carbide epitaxial layer 32. Silicon carbide single-crystal substrate 11 constitutes second main surface 10b of silicon carbide semiconductor substrate 10, and silicon carbide epitaxial layer 32 constitutes first main surface 10a of silicon carbide semiconductor substrate 10. Silicon carbide single-crystal substrate 11 is made of, for example, hexagonal crystal silicon carbide of polytype 4H, contains impurities such as nitrogen, and has a conductivity type of n-type (first conductivity type). The impurity concentration of silicon carbide single-crystal substrate 11 is, for example, about greater than or equal to 1×10¹⁸ cm⁻³ and less than or equal to 1×10¹⁹ cm⁻³.

Silicon carbide epitaxial layer 32 mainly has a drift region 12, a body region 13, a source region 14, a contact region 18, a JTE (Junction Termination Extension) region 4, a girdling region 5, a field stop region 6, and a buffer layer 3. Buffer layer 31 is an epitaxial layer provided in contact with silicon carbide single-crystal substrate 11 and made of silicon carbide. Drift region 12 is provided on buffer layer 31. Drift region 12 contains impurities such as nitrogen and has a conductivity type of n-type. The concentration of impurities such as nitrogen contained in drift region 12 is, for example, about greater than or equal to 1×10¹⁵ cm⁻³ and less than or equal to 1×10¹⁶ cm⁻³. The impurity concentration of drift region 12 is lower than the impurity concentration of buffer layer 31.

Body region 13 is provided in contact with drift region 12 and is exposed to first main surface 10a. Body region 13 contains impurities such as Al (aluminum) or B (boron) and has p-type (second conductivity type). The impurity concentration of body region 13 is, for example, about 1×10¹⁷ cm⁻³.

Source region 14 is provided so as to be surrounded by body region 13 and is exposed to first main surface 10a. Source region 14 is isolated from drift region 12 by body region 13. Source region 14 contains impurities such as P (phosphorus) and has a conductivity type of n-type. The impurity concentration of source region 14 is, for example, about 1×10²⁰ cm⁻³. The impurity concentration of source region 14 is higher than the impurity concentration of drift region 12. It is configured such that a channel CH can be formed in a region of body region 13 between source region 14 and drift region 12.

Contact region 18 is provided so as to be surrounded by source region 14 and is exposed to first main surface 10a. Contact region 18 is provided in contact with source region 14 and body region 13. Contact region 18 contains impurities such as Al (aluminum) or B (boron) and has p-type. The impurity concentration of contact region 18 is, for example, about 1×10²⁰ cm⁻³. The impurity concentration of contact region 18 is higher than the impurity concentration of body region 13. JTE region 4 and girdling region 5 are provided near an outer circumference of silicon carbide semiconductor substrate 10 and are exposed to first main surface 10a. JTE region 4 is provided in contact with body region 13. Girdling region 5 is spaced apart from JTE region 4 and provided in plural on an outer side of JTE region 4. JTE region 4 and girdling region 5 contain impurities such as Al (aluminum) or B (boron) and have p-type. The dose amount of JTE region 4 and girdling region 5 is, for example, about 1.3×10¹³ cm⁻².

Field stop region 6 is provided so as to surround girdling region 5 in a plan view (viewed from a direction perpendicular to first main surface 10a of silicon carbide semiconductor substrate 10) and is exposed to first main surface 10a. Field stop region 6 contains impurities such as P (phosphorus) and has a conductivity type of n-type. The impurity concentration of field stop region 6 is, for example, about 1×10¹⁸ cm⁻³. The impurity concentration of field stop region 6 is higher than the impurity concentration of drift region 12.

Gate insulating film 15a is in contact with first main surface 10a of silicon carbide semiconductor substrate 10 and is formed on first main surface 10a of silicon carbide semiconductor substrate 10 so as to extend from one upper surface of source region 14 to another upper surface of source region 14. Gate insulating film 15a is provided in contact with source region 14, body region 13, and drift region 12.Breakdown voltage holding portion 15c is provided on first main surface 10a of silicon carbide semiconductor substrate 10 so as to be in contact with JTE region 4, girdling region 5, and field stop region 6. Breakdown voltage holding portion 15c is exposed to a plane along outer circumferential end portion 10c of silicon carbide semiconductor substrate 10. Each of gate insulating film 15a and breakdown voltage holding portion 15c is made of, for example, silicon dioxide.

Gate electrode 27 is arranged in contact with gate insulating film 15a. Gate electrode 27 is provided at a position of facing source region 14, body region 13, and drift region 12. Gate electrode 27 is constituted of a conductor such as doped polysilicon or Al.

Source electrode 16 (first electrode 16) is in contact with first main surface 10a of silicon carbide semiconductor substrate 10 and in ohmic junction with silicon carbide semiconductor substrate 10. Source electrode 16 contains, for example, titanium (Ti), aluminum (Al), and silicon (Si), and is in contact with each of source region 14 and contact region 18. Preferably, source electrode 16 is in ohmic junction with each of source region 14 and contact region 18.

Interlayer insulating film 21 is provided in contact with gate electrode 27 and gate insulating film 15a. Interlayer insulating film 21 provides electrical insulation between gate electrode 27 and source electrode 16. Interlayer insulating film 21 is provided on breakdown voltage holding portion 15c. Source interconnection 19 is formed so as to be in contact with source electrode 16 and cover interlayer insulating film 21. Source interconnection 19 is made of a conductor such as Al. Source interconnection 19 is electrically connected to source region 14 through source electrode 16.

Drain electrode 20 is in contact with second main surface 10b of silicon carbide semiconductor substrate 10 and in ohmic junction with silicon carbide semiconductor substrate 10. Drain electrode 20 may be, for example, NiSi (nickel silicon) or may be the same material as source electrode 16. Drain electrode 20 is electrically connected to silicon carbide single-crystal substrate 11. Drain electrode 20 has third main surface 20a in contact with second main surface 10b of silicon carbide semiconductor substrate 10 and fourth main surface 20b opposite to third main surface 20a.

Referring to FIG. 1, second main surface 10b of silicon carbide single-crystal substrate 11 is provided with a recess TQ having a side wall surface A constituted of silicon carbide single-crystal substrate 11. A bottom portion B of recess TQ constitutes second main surface 10b of silicon carbide single-crystal substrate 11. Silicon carbide single-crystal substrate 11 is constituted of a base portion 11b and a side wall portion 11a. Side wall portion 11a of silicon carbide single-crystal substrate 11 is formed so as to be exposed to a plane along outer circumferential end portion 10c of silicon carbide semiconductor substrate 10. In other words, recess TQ is formed so as to maintain side wall portion 11a of silicon carbide single-crystal substrate 11 at outer circumferential end portion 10c of silicon carbide semiconductor substrate 10 in a plan view. Side wall portion 11a of silicon carbide single-crystal substrate 11 constitutes side wall surface A of recess TQ, and base portion 11b of silicon carbide single-crystal substrate 11 constitutes bottom portion B. Drain electrode 20 is provided so as to be in contact with each of side wall surface A and bottom portion B of recess TQ and enter recess TQ.

Metal layer 22 is provided so as to be in contact with fourth main surface 20b of second electrode 20 and enter the above-described recess. Metal layer 22 preferably contains Cu (copper) and is made of, for example, Cu or CuW (copper tungsten). A thickness T2 of metal layer 22 is greater than a thickness T1 of silicon carbide semiconductor substrate 10. It should be noted that, when recess TQ is provided in second main surface 10b of silicon carbide semiconductor substrate 10, thickness T1 of silicon carbide semiconductor substrate 10 is a distance from first main surface 10a to bottom portion B of recess TQ along a normal line direction of first main surface 10a of silicon carbide semiconductor substrate 10. Thickness T1 of silicon carbide semiconductor substrate 10 is, for example, about 100 μm. Thickness T2 of metal layer 22 is, for example, about greater than or equal to 50 μm and less than or equal to 300 μm, and preferably is about greater than or equal to 100 μm and less than or equal to 200 μm.

Backside surface protecting electrode 23 is provided in contact with silicon carbide single-crystal substrate 11, drain electrode 20, and metal layer 22. Backside surface protecting electrode 23 has a layered structure constituted of, for example, a Ti layer, a Pt layer, and an Au layer. Next, a method for manufacturing MOSFET 1 as silicon carbide semiconductor device 1 in accordance with the first embodiment of the present invention will be described.

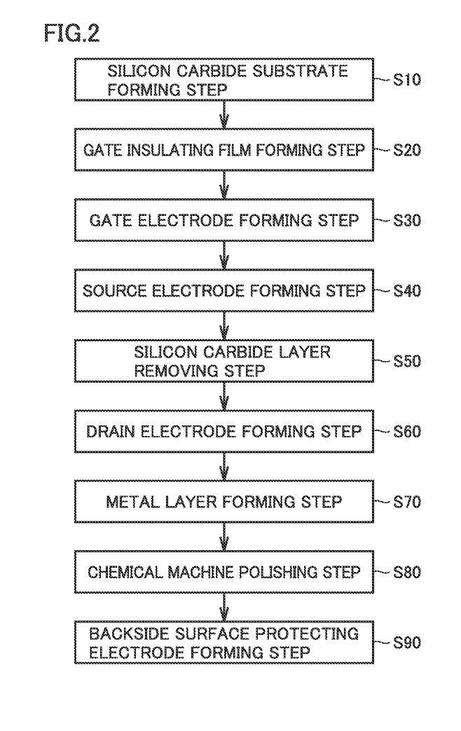

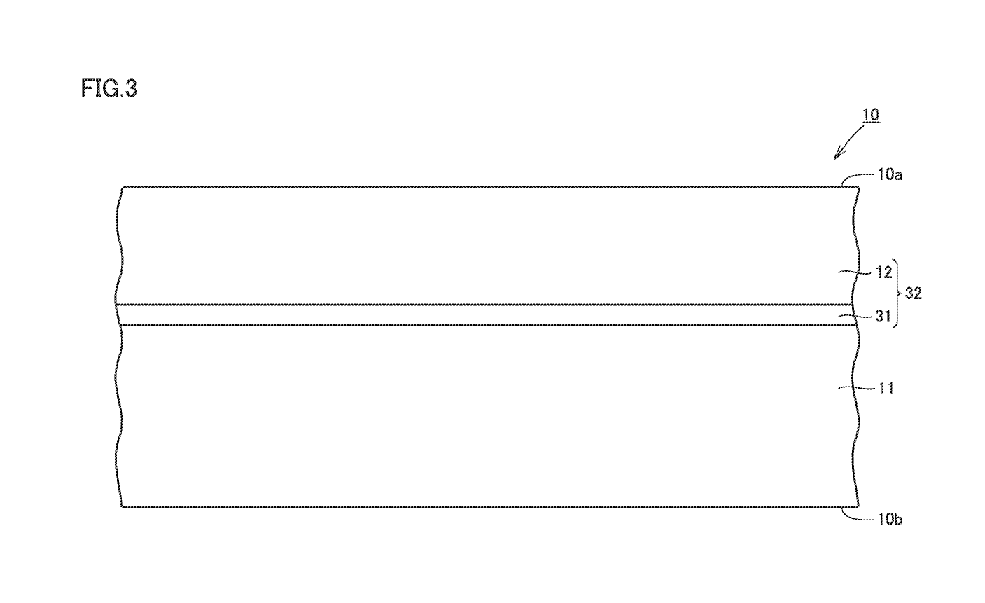

Firstly, the silicon carbide substrate forming step (S10: FIG. 2) is performed. For example, by slicing an ingot (not illustrated) made of silicon carbide single crystal of polytype 4H, silicon carbide single-crystal substrate 11 being made of hexagonal crystal silicon carbide of polytype 4H and having a conductivity type of n-type (first conductivity type) is prepared. Referring to FIG. 3, silicon carbide epitaxial layer 32 made of, for example, silicon carbide and having a conductivity type of n-type is formed on silicon carbide single-crystal substrate 11. Silicon carbide epitaxial layer 32 may include buffer layer 31 provided on silicon carbide single-crystal substrate 11 and drift region 12 provided on buffer layer 31. By the manner described above, silicon carbide semiconductor substrate 10 having first main surface 10a and second main surface 10b opposite to first main surface 10a is prepared. Silicon carbide semiconductor substrate 10 includes silicon carbide single-crystal substrate 11 constituting second main surface 10b, and silicon carbide epitaxial layer 32 being provided in contact with silicon carbide single-crystal substrate 11 and constituting first main surface 10a.

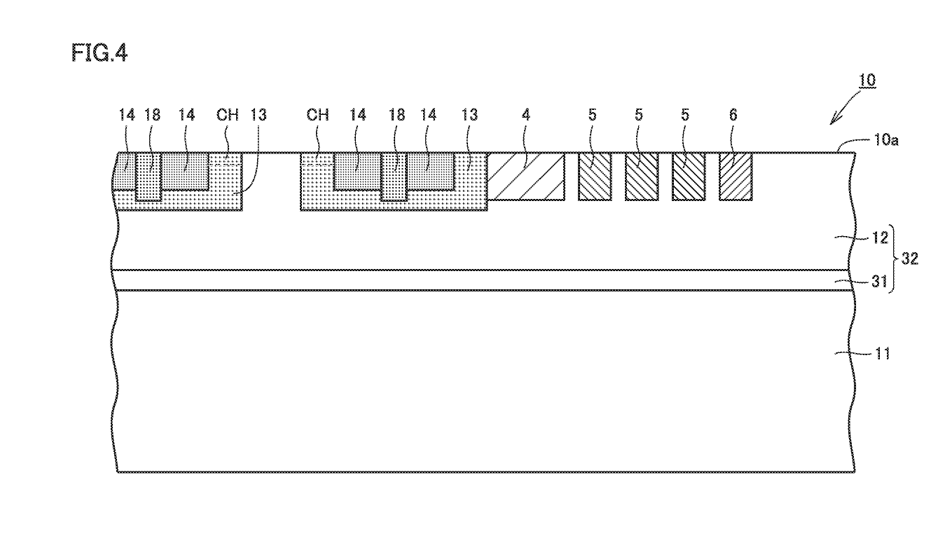

Next, the ion implantation step is performed. Referring to FIG. 4, for example, Al (aluminum) ion is implanted to first main surface 10a of silicon carbide semiconductor substrate 10, so that body region 13 having a conductivity type of p-type is formed in silicon carbide epitaxial layer 32. Next, for example, P (phosphorus) ion is implanted to body region 13 with a depth smaller than the implantation depth of the above-described Al ion, so that source region 14 having a conductivity type of n-type is formed. Next, for example, Al ion is implanted to source region 14, so that contact region 18 being adjacent to source region 14, having substantially the same depth as source region 14, and having a conductivity type of p-type is formed. Similarly, for example, by introducing Al ion near an outer circumference of silicon carbide semiconductor substrate 10, JTE region 4 and girdling region 5 having a conductivity type of p-type are formed. Moreover, for example, by implanting P (phosphorus) ion to first main surface 10a of silicon carbide semiconductor substrate 10, field stop region 6 having a conductivity type of n-type is formed.

Next, the activation annealing step is performed. Specifically, by heating silicon carbide semiconductor substrate 10 at a temperature of, for example, 1700° C. for about 30 minutes, impurities introduced in the ion implantation step are activated. Accordingly, a desired carrier is generated in the region where the impurities are introduced.

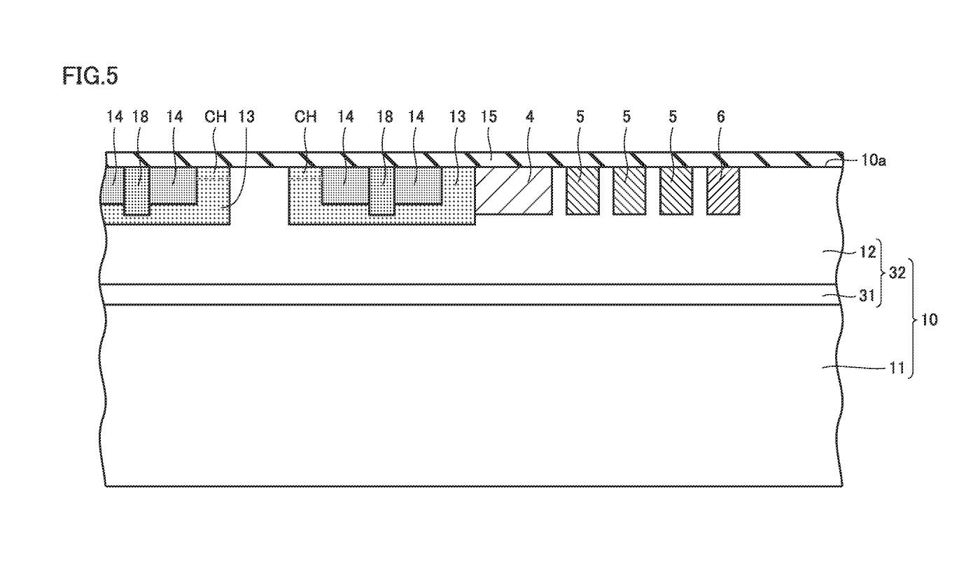

Next, the gate insulating film forming step (S20: FIG. 2) is performed. Specifically, referring to FIG. 5, by heating silicon carbide semiconductor substrate 10 in an atmosphere containing, for example, oxygen, insulating film 15 constituted of silicon dioxide is formed so as to cover first main surface 10a. Insulating film 15 is formed in first main surface 10a so as to be in contact with body region 13, source region 14, contact region 18, JTE region 4, girdling region 5, and field stop region 6.

Next, the gate electrode forming step (S30: FIG. 2) is performed. For example, by an LP-CVD (Low Pressure Chemical Vapor Deposition) method, gate electrode 27 being in contact with gate insulating film 15a and made of polysilicon containing impurities is formed. Next, for example by a P (Plasma)-CVD method, interlayer insulating film 21 made of silicon dioxide is formed so as to cover gate insulating film 15a and gate electrode 27.

Next, the source electrode forming step (S40: FIG. 2) is performed. Specifically, interlayer insulating film 21 and insulating film 15 are removed from the region where source electrode 16 should be formed, and source region 14 and contact region 18 are exposed from insulating film 15. Next, for example by sputtering, in the region where source region 14 and contact region 18 are exposed from insulating film 15, metal layer 22 containing, for example, NiSi (nickel silicon) or TiAlSi (titanium aluminum silicon) is formed. Next, by heating above-described metal layer 22, at least a portion of above-described metal layer 22 is silicided, so that source electrode 16 (first electrode 16) in ohmic junction with silicon carbide semiconductor substrate 10 is formed.

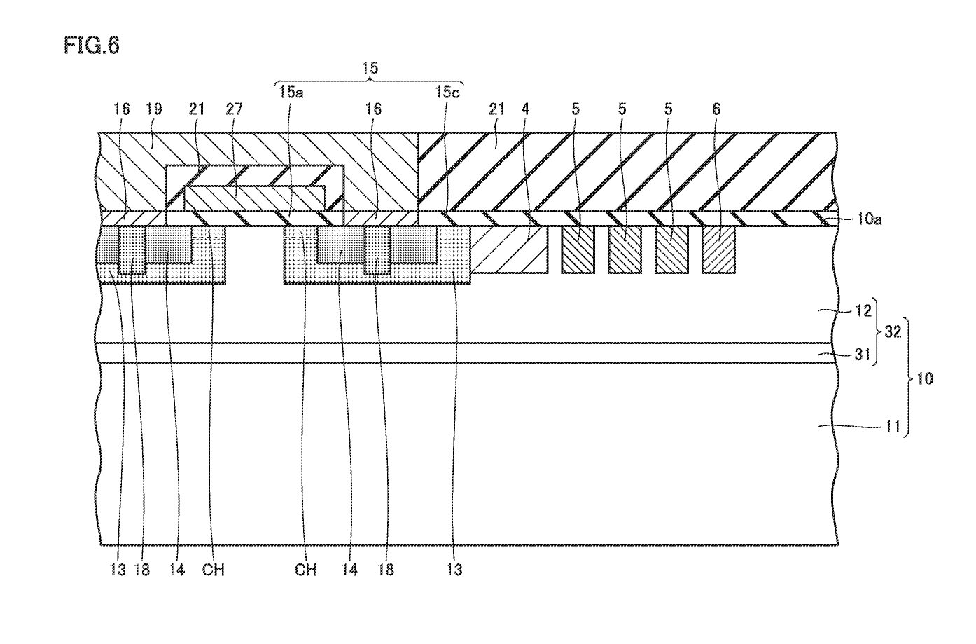

Next, the source interconnection forming step is performed. Specifically, for example by sputtering, a first electrode layer (not illustrated) made of Ta, TaN, Ti, TiN, or TiW is formed so as to be in contact with source electrode 16. Next, a second electrode layer (not illustrated) made of Al, AlSi, or AlSiCu is formed on the first electrode layer. Accordingly, source interconnection 19 having a structure in which the above-described electrode layers are layered is formed (refer to FIG. 6). Moreover, as the first electrode layer, the one having a structure in which electrode layers made of Ta and TaN are layered may be formed.

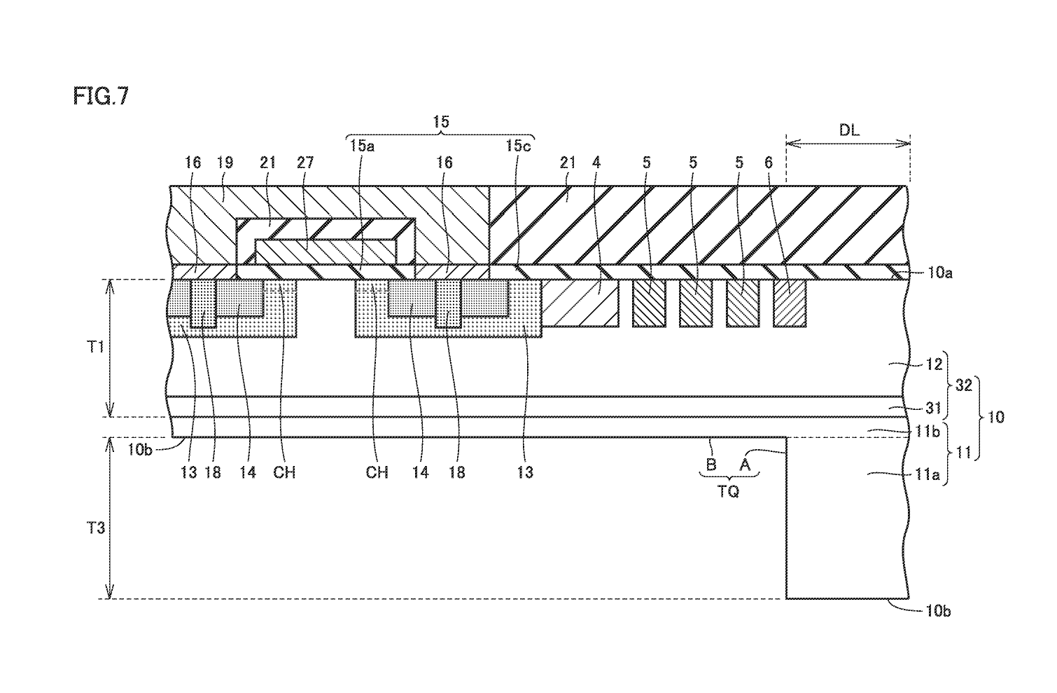

Next, the silicon carbide layer removing step (S50: FIG. 2) is performed. Specifically, at least a portion of silicon carbide semiconductor substrate 10 on a side of second main surface 10b is removed. Referring to FIG. 7, a portion of silicon carbide single-crystal substrate 11 is removed for example by etching, so that a recess TQ is formed in second main surface 10b of silicon carbide semiconductor substrate 10. Silicon carbide single-crystal substrate 11 from which a portion of silicon carbide single-crystal substrate 11 is removed may be constituted of a base portion 11b in contact with buffer layer 31 and a side wall portion 11a extending in a direction perpendicular to first main surface 10a from base portion 11b. Base portion 11b constitutes bottom portion B of recess TQ, and side wall portion 11a constitutes side wall surface A of recess TQ. In other words, recess TQ is formed by side wall surface A and bottom portion B.

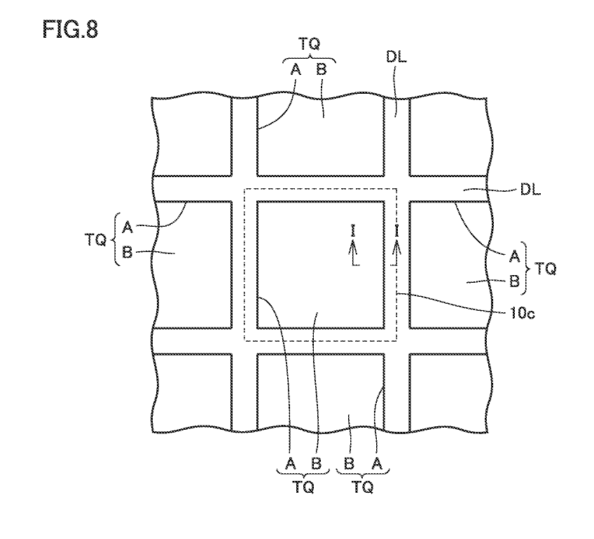

Referring to FIGS. 7 and 8, recess TQ is formed such that side wall portion 11 a of silicon carbide single-crystal substrate 11 remains along a dicing line DL. The dicing line is a position at which silicon carbide semiconductor substrate 10 is cut in the dicing line forming step described later. As shown in FIG. 8, in a plan view, the dicing line is formed like a lattice extending in a vertical direction and a lateral direction to transverse first main surface 10a of silicon carbide semiconductor substrate 10. In FIG. 8, the broken line indicates an outer circumferential end portion 10c of silicon carbide semiconductor device 1 after silicon carbide semiconductor substrate 10 is cut in the dicing step. In other words, in a plan view, recess TQ is formed so as to maintain side wall portion 11a of silicon carbide single-crystal substrate 11 at outer circumferential end portion 10c of silicon carbide semiconductor substrate 10. A thickness T3 of the portion removed in the silicon carbide layer removing step is, for example, greater than or equal to 250 μm and less than or equal to 500 μm. The thickness of side wall portion 11a of silicon carbide single-crystal substrate 11 may be the same thickness as the removed portion.

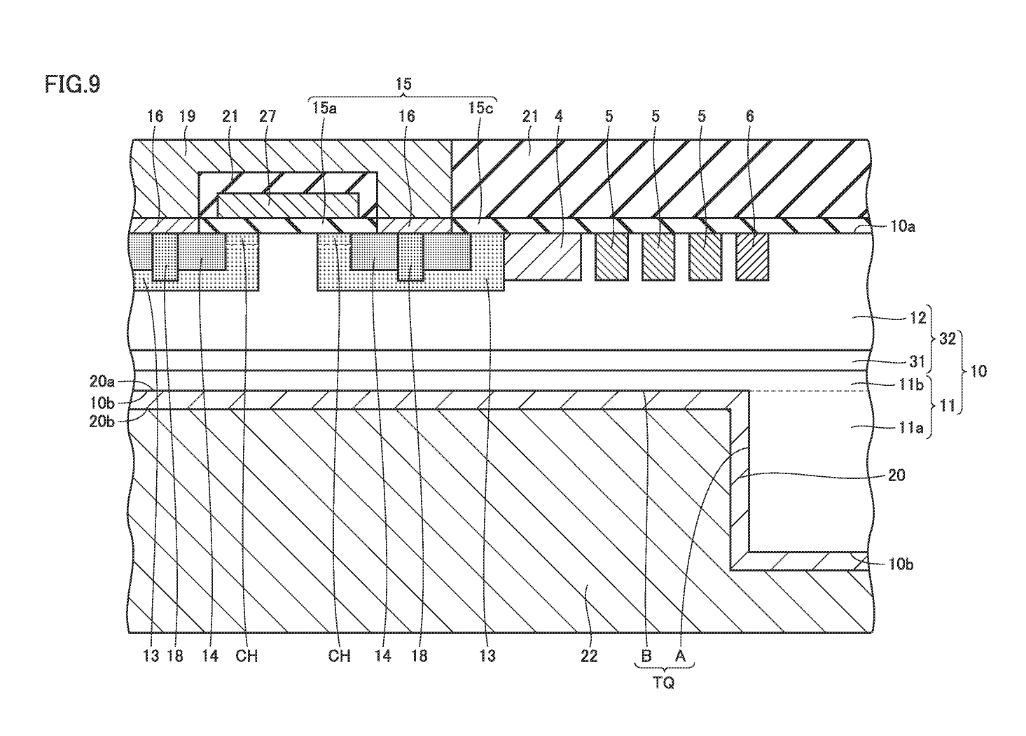

Next, the drain electrode forming step (S60: FIG. 2) is performed. Referring to FIG. 9, metal layer 22 is formed in contact with second main surface 10b of silicon carbide single-crystal substrate 11. Specifically, metal layer 22 made of, for example, NiSi is formed so as to be in contact with second main surface 10b of base portion 11b of silicon carbide single-crystal substrate 11 (in other words, the bottom portion of the recess), the side wall surface of the recess, and second main surface 10b of side wall portion 11a of silicon carbide single-crystal substrate 11. Metal layer 22 may be, for example, TiAlSi. Formation of metal layer 22 is performed preferably by a sputtering method. Formation of metal layer 22 may be performed by evaporation. Next, by heating metal layer 22, metal layer 22 is alloyed to become drain electrode 20. By heating above-described layer 22 to, for example, about 1000° C. by using, for example, laser irradiation, at least a portion of above-described metal layer 22 is silicided to become drain electrode 20. Drain electrode 20 is in ohmic junction with silicon carbide single-crystal substrate 11. As described above, drain electrode 20 (second electrode 20) having a third main surface 20a in contact with second main surface 10b of silicon carbide semiconductor substrate 10 exposed by the silicon carbide layer removing step and a fourth main surface 20b opposite to third main surface 20a is formed.

Next, the metal layer forming step (S70: FIG. 2) is performed. Referring to FIG. 9, metal layer 22 is formed in contact with fourth main surface 20b of drain electrode 20 so as to be in electrical contact with fourth main surface 20b of drain electrode 20. Preferably, metal layer 22 is formed so as to cover an entire surface of fourth main surface 20b of drain electrode 20. Metal layer 22 is formed so as to enter recess TQ provided in second main surface 10b of silicon carbide single-crystal substrate 11 and cover second main surface 10b of side wall portion 11 a of silicon carbide single-crystal substrate 11. In other words, metal layer 22 is in contact with second main surface 10b of base portion 11b of silicon carbide single-crystal substrate 11 (in other words, bottom portion B), side wall surface A of recess TQ, and second main surface 10b of side wall portion 11a of silicon carbide single-crystal substrate 11 through drain electrode 20.

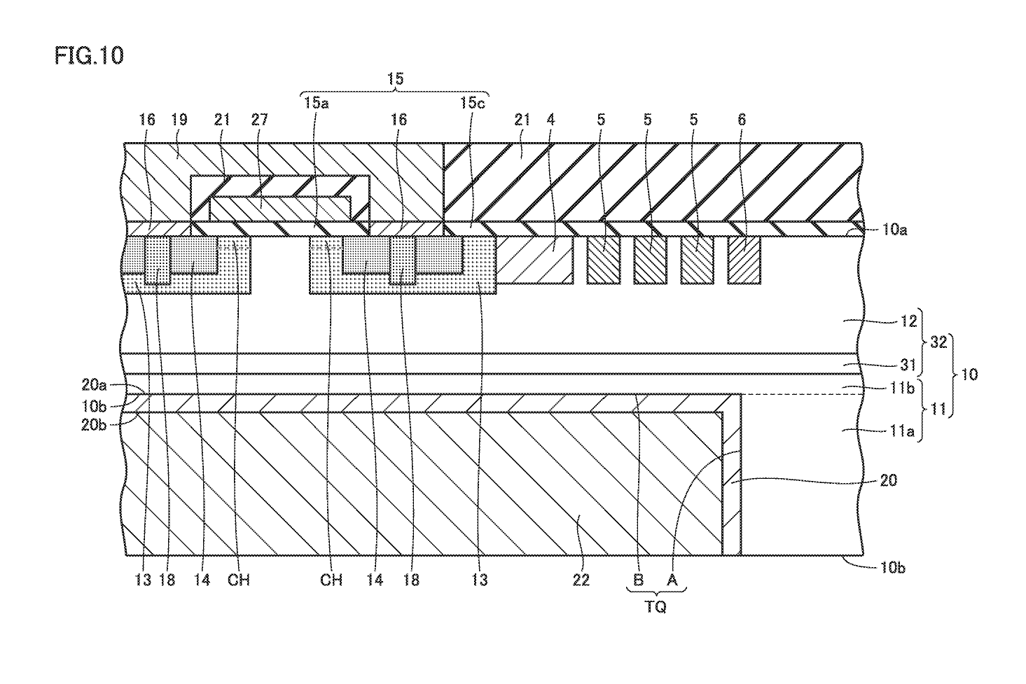

Next, the chemical machine polishing step (S80: FIG. 2) is performed. Referring to FIG. 10, after the metal layer 22 forming step, a portion of metal layer 22 and a portion of drain electrode 20 are removed by chemical machine polishing so that second main surface 10b of side wall portion 11a of silicon carbide semiconductor substrate 10 is exposed. Accordingly, metal layer 22, drain electrode 20, and second main surface 10b of side wall portion 11a of silicon carbide semiconductor substrate 10 are exposed. In a plan view, a total area of metal layer 22 after the chemical machine polishing step is preferably larger than or equal to 95% of a second area of silicon carbide semiconductor substrate 10 before the recess is formed in second main surface 10b of silicon carbide semiconductor substrate 10. The thickness of silicon carbide single-crystal substrate 11 after the chemical machine polishing step (in other words, a sum of the thickness of base portion 11b and the thickness of side wall portion 11a) is preferably less than or equal to 200 μm. The thickness of metal layer 22 is adjusted such that thickness T2 of metal layer 22 becomes greater than thickness T1 of the silicon carbide semiconductor substrate after the silicon carbide layer removing step.

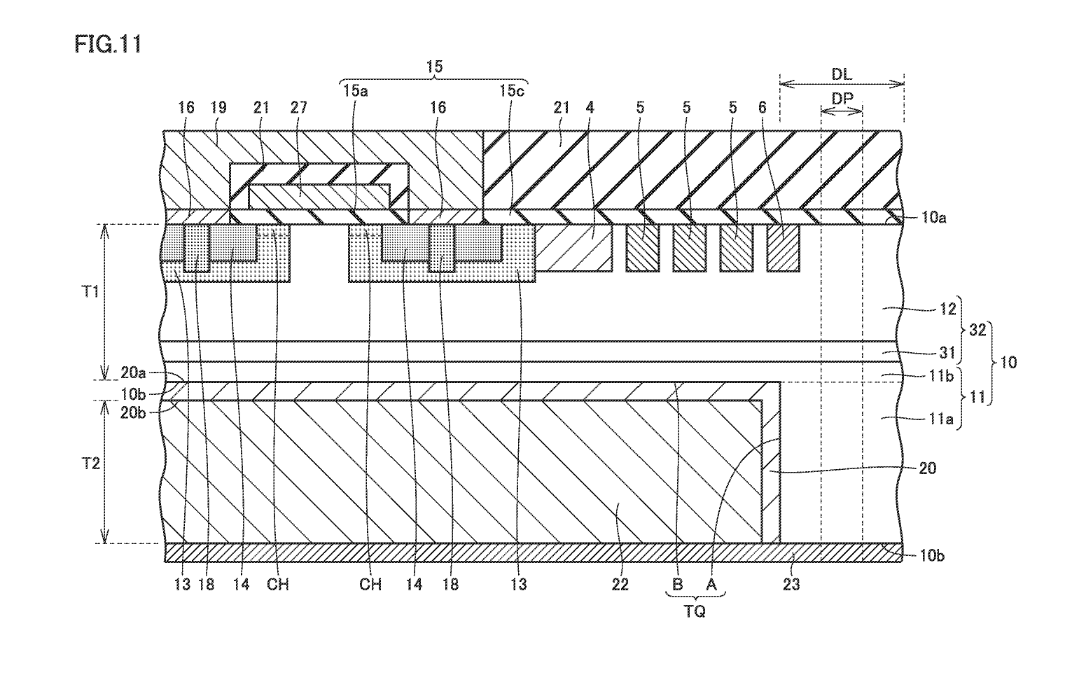

Next, the backside surface protecting electrode forming step (S90: FIG. 2) is performed. Specifically, referring to FIG. 11, a backside surface protecting electrode 23 is formed so as to be in contact with metal layer 22, drain electrode 20, and second main surface 10b of side wall portion 11a of silicon carbide single-crystal substrate 11. Backside surface protecting electrode 23 includes, for example, a Ti layer, a Pt layer, and an Au layer. Specifically, by sputtering for example, the Ti layer is formed so as to be in contact with drain electrode 20. Next, by sputtering for example, the Pt layer is formed in contact with the Ti layer. Next, by sputtering, the Au layer is formed in contact with the Pt layer. In such a manner, backside surface protecting electrode 23 including the Ti layer, the Pt layer, and the Au layer is formed.

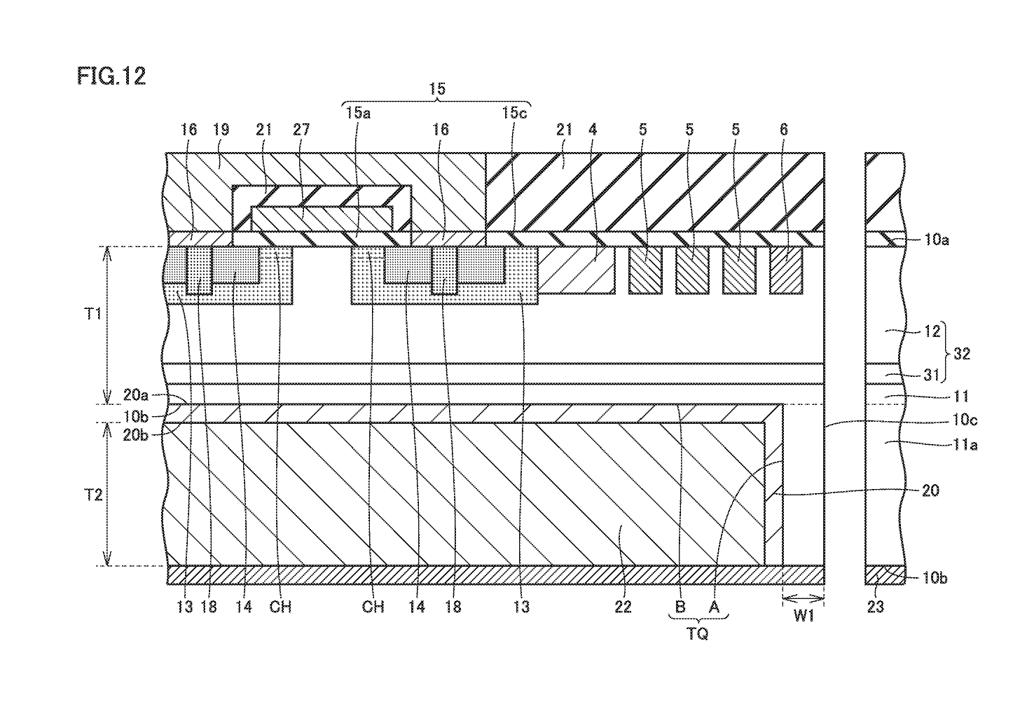

Next, the dicing step is performed. Specifically, referring to FIGS. 11 and 12, silicon carbide semiconductor substrate 10 and the backside surface protecting electrode are cut along dicing line DL, so that a plurality of semiconductor chips are obtained. Dicing may be performed by, for example, laser dicing or scribing. A width of a dicing portion DP where a silicon carbide portion of silicon carbide semiconductor substrate 10 is removed may be smaller than a width of dicing line DL of silicon carbide semiconductor substrate 10. Side wall portion 11a of silicon carbide single-crystal substrate 11 is formed so as to be exposed to outer circumferential end portion 10c of silicon carbide semiconductor substrate 10 after the dicing step. A distance from outer circumferential end portion 10c of silicon carbide semiconductor substrate 10 to metal layer 22 (in other words, width W1 of side wall portion 11a of silicon carbide single-crystal substrate 11 after the dicing step) is preferably less than 100 μm. By performing the steps described above, MOSFET 1 as silicon carbide semiconductor device 1 is manufactured.

Next, functions and effects of MOSFET 1 in accordance with the first embodiment will be described.

According to the method for manufacturing silicon carbide semiconductor device 1 in accordance with the first embodiment, metal layer 22 in electrical contact with fourth main surface 20b of second electrode 20 is formed. The thickness of metal layer 22 is greater than the thickness of silicon carbide semiconductor substrate 10 after the step of removing at least a portion of silicon carbide semiconductor substrate 10 on a side of second main surface 10b. Accordingly, the on-resistance of silicon carbide semiconductor device 1 can be reduced. Moreover, by forming metal layer 22 in contact with fourth main surface 20 of second electrode 20, the rigidity can be maintained high to the extent that silicon carbide semiconductor device 1 can be self-supported.

Moreover, according to the method for manufacturing silicon carbide semiconductor device 1 in accordance with the first embodiment, the step of removing at least a portion of silicon carbide semiconductor substrate 10 on a side of second main surface 10b includes the step of forming the recess in second main surface 10b of silicon carbide semiconductor substrate 10. The step of forming metal layer 22 includes the step of forming metal layer 22 entering the recess and covering second main surface 10b. The step of removing a portion of metal layer 22 by chemical machine polishing so that second main surface 10b of silicon carbide semiconductor substrate 10 is exposed after the step of forming metal layer 22 is further included. Accordingly, the on-resistance of silicon carbide semiconductor device 1 can be reduced effectively.

Further, according to the method for manufacturing silicon carbide semiconductor device 1 in accordance with the first embodiment, the step of forming the recess in second main surface 10b of silicon carbide semiconductor substrate 10 has the step of forming the recess so that silicon carbide single-crystal substrate 11 remains along the dicing line. Accordingly, dicing of silicon carbide semiconductor substrate 10 becomes easier than the case where metal layer 22 is formed along the dicing line.

Further, according to the method for manufacturing silicon carbide semiconductor device 1 in accordance with the first embodiment, the thickness of the portion removed by the step of removing at least a portion of silicon carbide semiconductor substrate 10 on the side of second main surface 10b is greater than or equal to 250 μm and less than or equal to 500 μm. By setting the thickness of the removed portion to be greater than or equal to 250 μm, on-resistance of silicon carbide semiconductor device 1 can be reduced effectively. By setting the thickness of the removed portion to be less than or equal to 500 μm, the rigidity can be maintained high to the extent that silicon carbide semiconductor device 1 can be self-supported.

Further, according to the method for manufacturing silicon carbide semiconductor device 1 in accordance with the first embodiment, the thickness of metal layer 22 is greater than or equal to 50 μm and less than or equal to 300 μm. By setting the thickness of metal layer 22 to be greater than or equal to 50 μm, the rigidity of silicon carbide semiconductor device 1 can be maintained high to the extent that silicon carbide semiconductor device 1 can be self-supported. By setting the thickness of metal layer 22 to be less than or equal to 300 μm, on-resistance of silicon carbide semiconductor device 1 can be reduced effectively.

According to silicon carbide semiconductor device 1 in accordance with the first embodiment, metal layer 22 is in electrical contact with fourth main surface 20b of drain electrode 20. The thickness of metal layer 22 is greater than the thickness of silicon carbide semiconductor substrate 10. Accordingly, the on-resistance of silicon carbide semiconductor device 1 can be reduced. Moreover, by forming metal layer 22 to be in contact with fourth main surface 22 of drain electrode 20, the rigidity can be maintained high to the extent that silicon carbide semiconductor device 1 can be self-supported.

Moreover, according to silicon carbide semiconductor device 1 in accordance with the first embodiment, silicon carbide semiconductor substrate 10 includes silicon carbide single-crystal substrate 11 being in contact with silicon carbide epitaxial layer 32 and constituting second main surface 10b. Accordingly, silicon carbide semiconductor device 1 with high rigidity can be obtained.

Further, according to silicon carbide semiconductor device 1 in accordance with the first embodiment, second main surface 10b of silicon carbide semiconductor substrate 10 is provided with the recess having the side wall portion constituted of silicon carbide single-crystal substrate 11. Second electrode 20 and metal layer 22 are provided so as to enter the recess. Accordingly, on-resistance of silicon carbide semiconductor device 1 can be reduced effectively.

Further, according to silicon carbide semiconductor device 1 in accordance with the first embodiment, recess TQ is formed so that silicon carbide single-crystal substrate 11 remains in the outer circumferential end portion of silicon carbide semiconductor substrate 10 in a plan view. Accordingly, while maintaining high rigidity of silicon carbide semiconductor device 1, on-resistance of silicon carbide semiconductor device 1 can be reduced effectively.

Further, according to silicon carbide semiconductor device 1 in accordance with the first embodiment, the thickness of metal layer 22 is greater than or equal to 50 μm and less than or equal to 300 μm. By setting the thickness of metal layer 22 to be greater than or equal to 50 μm, the rigidity of silicon carbide semiconductor device 1 can be maintained high to the extent that silicon carbide semiconductor device 1 can be self-supported. By setting the thickness of metal layer 22 to be less than or equal to 300 μm, the on-resistance of silicon carbide semiconductor device 1 can be reduced effectively.

Further, according to silicon carbide semiconductor device 1 in accordance with the first embodiment, metal layer 22 contains copper. Accordingly, while maintaining high rigidity of silicon carbide semiconductor device 1, on-resistance of silicon carbide semiconductor device 1 can be reduced effectively.

### Second Embodiment

Next, MOSFET 1 in accordance with the second embodiment of the present invention will be described. A structure of MOSFET 1 in accordance with the second embodiment is different from the structure of MOSFET 1 in accordance with the first embodiment in that side wall portion 11a of silicon carbide single-crystal substrate 11 is provided on an inner side than outer circumferential end portion 10c, and other configuration is the same as MOSFET 1 in accordance with the first embodiment. Hereinafter, the point which is different from the configuration of MOSFET 1 in accordance with the first embodiment will be mainly described.

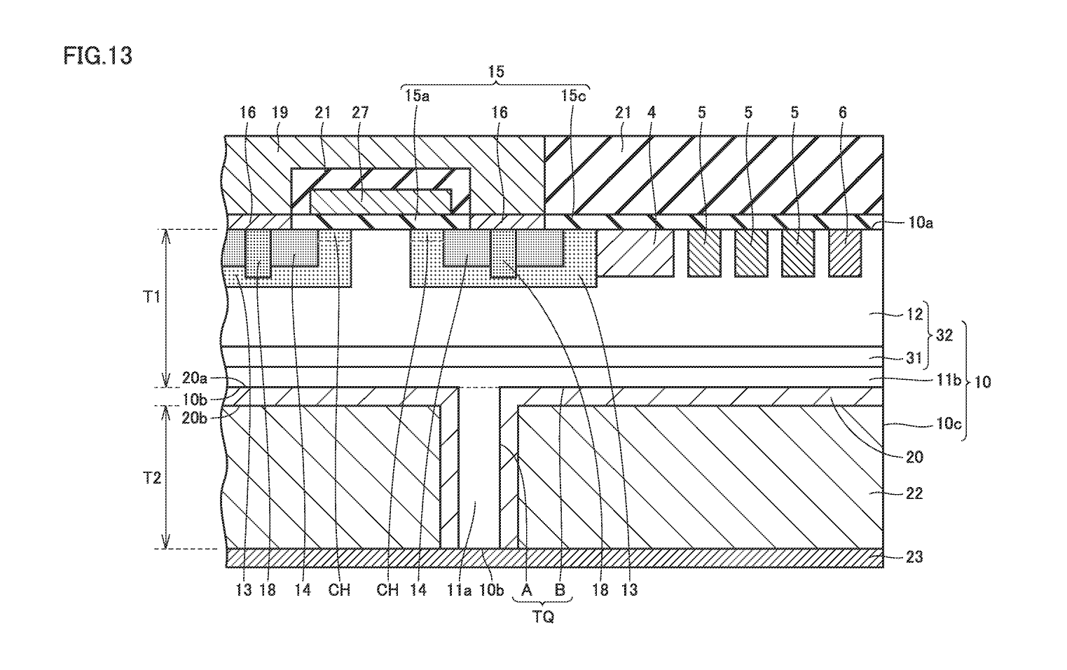

Referring to FIG. 13, silicon carbide single-crystal substrate 11 of MOSFET 1 in accordance with the second embodiment is constituted of base portion 11b and side wall portion 11a. Side wall portion 11a of silicon carbide single-crystal substrate 11 is provided on an inner side than outer circumferential end portion 10c of silicon carbide semiconductor substrate 10. Second main surface 10b of silicon carbide single-crystal substrate 11 is provided with a plurality of recesses TQ. Two recesses TQ adjacent to each other are spaced apart by side wall portion 11a of silicon carbide single-crystal substrate 11.

As shown in FIG. 13, in a cross section (viewed in a direction parallel to first main surface 10a of silicon carbide semiconductor substrate 10), side wall portion 11a of silicon carbide single-crystal substrate 11 is provided so as to be clamped between drain electrodes 20. Each of drain electrode 20 and metal layer 22 is provided so as to enter the recess. Metal layer 22 is provided so as to be exposed to a plane along outer circumferential end portion 10c of silicon carbide semiconductor substrate 10.

Next, a method for manufacturing MOSFET 1 in accordance with the second embodiment will be described. The method for manufacturing MOSFET 1 in accordance with the second embodiment is different from the method for manufacturing MOSFET 1 in accordance with the first embodiment in the silicon carbide removing step (S50), and other steps are substantially the same as the method for manufacturing MOSFET 1 in accordance with the first embodiment. Hereinafter, the point different from the configuration of MOSFET 1 in accordance with the first embodiment will be mainly described.

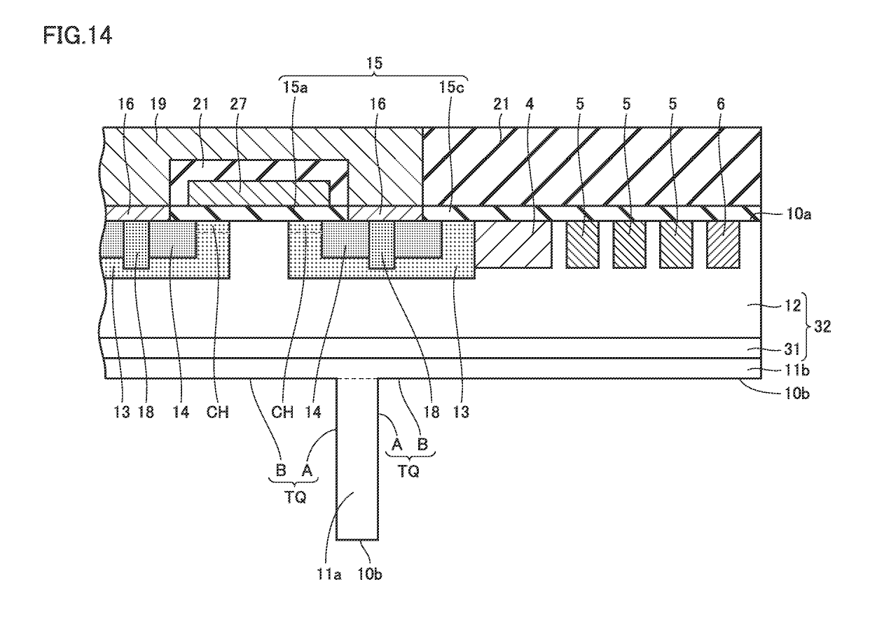

Referring to FIG. 14, in the silicon carbide layer removing step (S50: FIG. 2), a portion of silicon carbide single-crystal substrate 11 is removed for example by etching or the like, so that recess TQ is formed in second main surface 10b of silicon carbide semiconductor substrate 10. Silicon carbide single-crystal substrate 11 from which a portion of silicon carbide single-crystal substrate 11 is removed is constituted of base portion 11b in contact with buffer layer 31 and side wall portion 11a extending from base portion 11b in a direction perpendicular to first main surface 10a. Base portion 11b constitutes bottom portion B of recess TQ, and side wall portion 11a constitutes side wall surface A of recess TQ.

Recess TQ is formed in second main surface 10b of silicon carbide single-crystal substrate 11 so that side wall portion 11a of silicon carbide single-crystal substrate 11 is formed on an inner side than outer circumferential end portion 10c of silicon carbide semiconductor substrate 10. In a plan view, the shape of side wall portion 11a of silicon carbide single-crystal substrate 11 may be a lattice-like shape, a linear shape, or a honeycomb shape.

### Third Embodiment

Next, a configuration of MOSFET 1 in accordance with the third embodiment of the present invention will be described. A structure of MOSFET 1 in accordance with the third embodiment is different from the structure of MOSFET 1 in accordance with the first embodiment in that drain electrode 20 is provided in contact with buffer layer 31, and other configuration is the same as MOSFET 1 in accordance with the first embodiment. Hereinafter, the point different from the configuration of MOSFET 1 in accordance with the first embodiment will be mainly described.

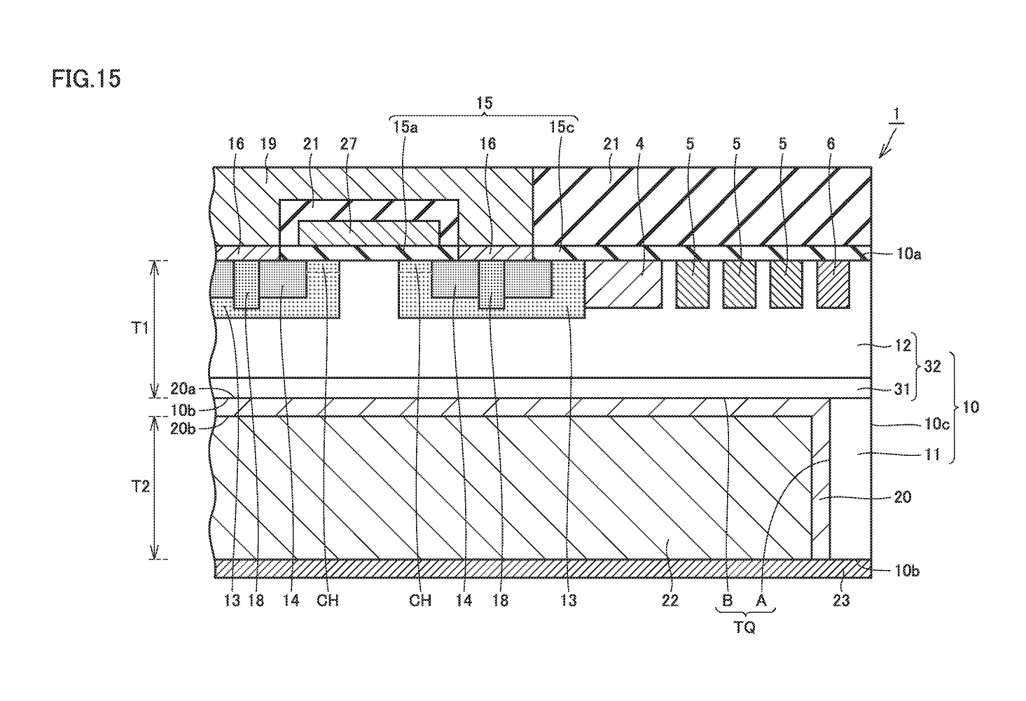

Referring to FIG. 15, silicon carbide single-crystal substrate 11 of MOSFET 1 in accordance with the third embodiment is provided so as to extend in a direction which is perpendicular to first main surface 10a of silicon carbide semiconductor substrate 10 along outer circumferential end portion 10c of silicon carbide semiconductor substrate 10. Recess TQ is formed in second main surface 10b of silicon carbide semiconductor substrate 10. Buffer layer 31 of silicon carbide epitaxial layer 32 constitutes bottom portion B, and silicon carbide semiconductor substrate 10 constitutes side wall surface A of recess TQ. In other words, bottom portion B of recess TQ is located at buffer layer 31 of silicon carbide epitaxial layer 32. Drain electrode 20 is provided in recess TQ so as to be in contact with buffer layer 31 of silicon carbide epitaxial layer 32 and silicon carbide single-crystal substrate 11. Metal layer 22 is provided in recess TQ and is in contact with drain electrode 20. Backside surface protecting electrode 23 is provided in contact with metal layer 22, drain electrode 20, and silicon carbide single-crystal substrate 11.

Next, a method for manufacturing MOSFET 1 in accordance with the third embodiment will be described. The method for manufacturing MOSFET 1 in accordance with the third embodiment is different from the method for manufacturing MOSFET 1 in accordance with the first embodiment in the silicon carbide removing step (S50), and other steps are substantially the same as the method for manufacturing MOSFET 1 in accordance with the first embodiment. Hereinafter, the point which is different from the configuration of MOSFET 1 in accordance with the first embodiment will be mainly described.

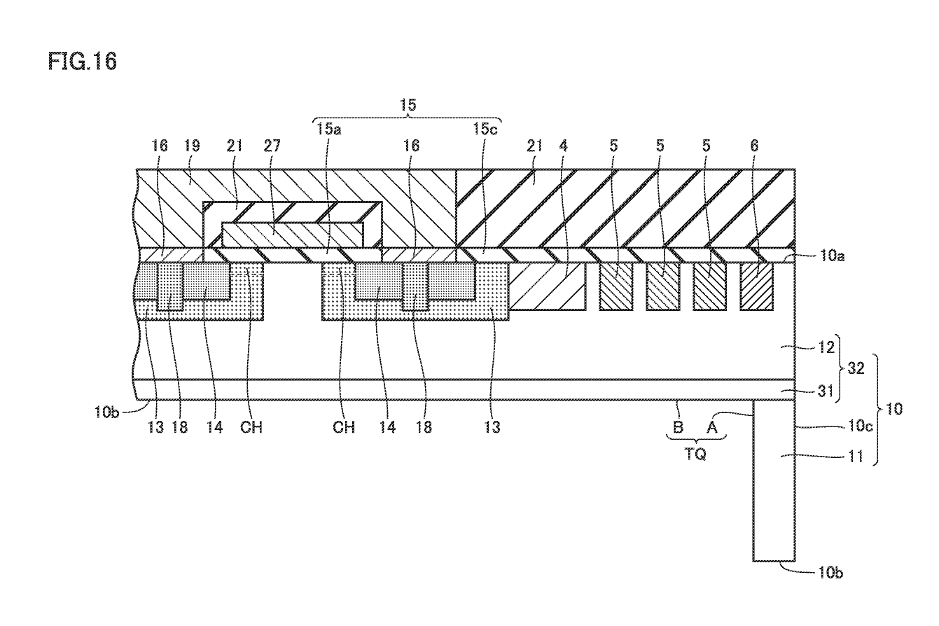

Referring to FIG. 16, in the silicon carbide layer removing step (S50: FIG. 2), a portion of silicon carbide single-crystal substrate 11 is removed, for example, by etching or the like, so that recess TQ is formed in second main surface 10b of silicon carbide semiconductor substrate 10. By removing silicon carbide single-crystal substrate 11 such that a portion of buffer layer 31 of silicon carbide epitaxial layer 32 is exposed, recess TQ is formed such that bottom portion B of recess TQ is located at silicon carbide epitaxial layer 32. In other words, silicon carbide single-crystal substrate 11 extending from buffer layer 31 in a direction which is perpendicular to first main surface 10a along outer circumferential end portion 10c of silicon carbide semiconductor substrate 10 remains. Buffer layer 31 of silicon carbide epitaxial layer 32 constitutes bottom portion B of recess TQ, and silicon carbide single-crystal substrate 11 constitutes side wall surface A of recess TQ. It should be noted that, in the silicon carbide removing step, a portion of buffer layer 31 may be removed, or buffer layer 31 may be removed until the drift layer is exposed.

According to the method for manufacturing silicon carbide semiconductor device 1 in accordance with the third embodiment, the step of forming recess TQ in second main surface 10b of silicon carbide semiconductor substrate 10 has the step of forming recess TQ so that bottom portion B of recess TQ is located at silicon carbide epitaxial layer 32. Accordingly, on-resistance of silicon carbide semiconductor device 1 can be reduced effectively.

According to the method for manufacturing silicon carbide semiconductor device 1, bottom portion B of recess TQ is located in silicon carbide epitaxial layer 32. Accordingly, on-resistance of silicon carbide semiconductor device 1 can be reduced effectively.

### Fourth Embodiment

Next, a configuration of MOSFET 1 in accordance with the fourth embodiment of the present invention will be described. A structure of MOSFET 1 in accordance with the fourth embodiment is different from the structure of MOSFET 1 in accordance with the third embodiment in that silicon carbide single-crystal substrate 11 is not provided and in that metal layer 22 covers an entire surface of second main surface 10b of silicon carbide semiconductor substrate 10, and other configuration is the same as MOSFET 1 in accordance with the third embodiment. Hereinafter, the point which is different from the configuration of MOSFET 1 in accordance with the third embodiment will be mainly described.

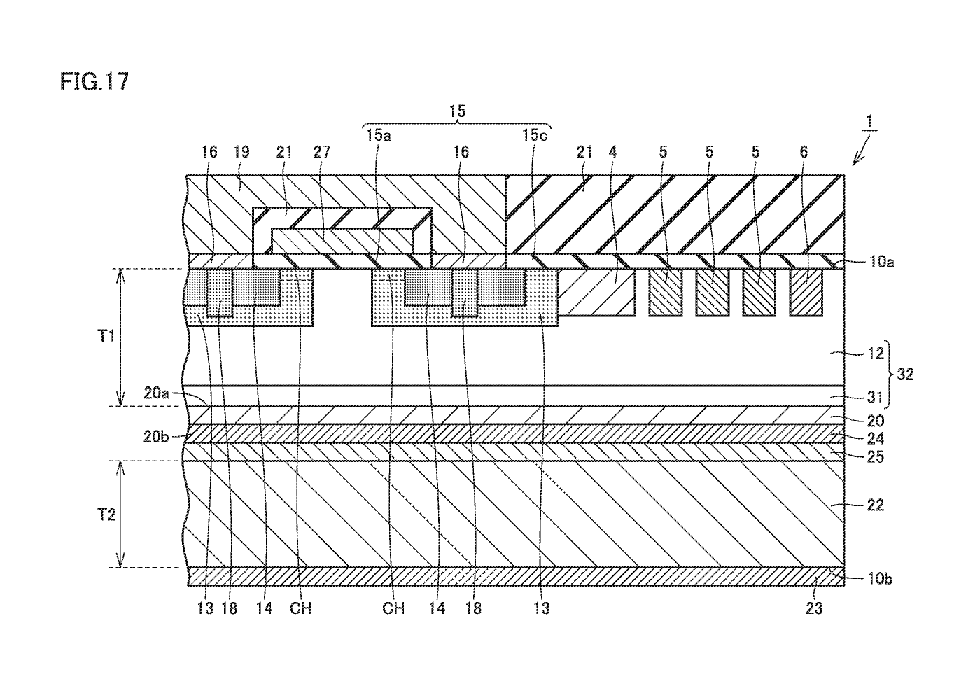

Referring to FIG. 17, MOSFET 1 in accordance with the fourth embodiment does not have silicon carbide single-crystal substrate 11, and drain electrode 20 is in contact with an entire surface of buffer layer 31 of silicon carbide epitaxial layer 32. In other words, drain electrode 20 is provided in contact with an entire surface of second main surface 10b of silicon carbide epitaxial layer 32. Backside surface protecting electrode 24 is provided in contact with an entire surface of fourth main surface 20b of drain electrode 20. Solder layer 25 is provided in contact with an entire surface of backside surface protecting electrode 24. Metal layer 22 is electrically connected to drain electrode 20 through backside surface protecting electrode 24 and solder layer 25. Metal layer 22 is provided so as to cover an entire surface of fourth main surface 20b of drain electrode 20. Backside surface protecting electrode 23 is provided so as to cover an entire surface of metal layer 22. It should be noted that each of backside surface protecting electrode 23 and backside surface protecting electrode 24 may have a layered structure constituted of a Ti layer, a Pt layer, and an Au layer.

Next, a method for manufacturing MOSFET 1 in accordance with the fourth embodiment will be described. The method for manufacturing MOSFET 1 in accordance with the fourth embodiment is different from the method for manufacturing MOSFET 1 in accordance with the third embodiment in the silicon carbide removing step (S50), and other steps are substantially the same as the method for manufacturing MOSFET 1 in accordance with the third embodiment. Hereinafter, the point different from the configuration of MOSFET 1 in accordance with the third embodiment will be mainly described.

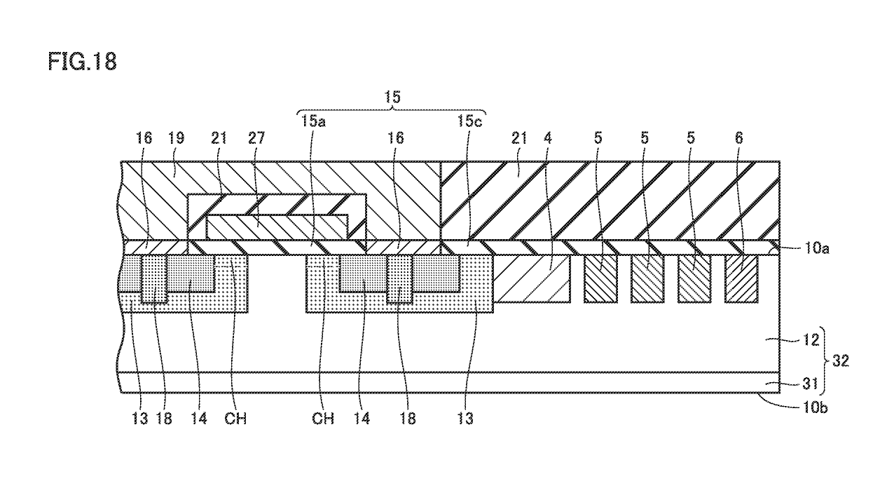

Referring to FIG. 18, in the silicon carbide layer removing step (S50: FIG. 2), silicon carbide single-crystal substrate 11 is entirely removed, for example, by grinding or polishing, so that buffer layer 31 of silicon carbide epitaxial layer 32 is exposed. In the silicon carbide removing step, a portion of buffer layer 31 may be removed, or buffer layer 31 may be removed until drift region 12 is exposed. In other words, in the silicon carbide layer removing step, all of silicon carbide single-crystal substrate 11 and a portion of silicon carbide epitaxial layer 32 are removed. A sum of the thickness of removed silicon carbide single-crystal substrate 11 and the thickness of silicon carbide epitaxial layer 32 is, for example, greater than or equal to 250 μm and less than or equal to 500 μm.

Next, drain electrode 20 is formed on an entire surface of second main surface 10b of silicon carbide semiconductor substrate 10 where silicon carbide epitaxial layer 32 is exposed. Backside surface protecting electrode 24 is formed on an entire surface of fourth main surface 20b of drain electrode 20.

Next, metal layer 22 is prepared which has solder layer 25 provided on one main surface and backside surface protecting electrode 23 provided on the other main surface. The thickness of metal layer 22 is, for example, about greater than or equal to 50 μm and less than or equal to 300 μm, and preferably about greater than or equal to 100 μm and less than or equal to 200 μm. Metal layer 22 is, for example, a copper plate. For example, metal layer 22 is arranged so that solder layer 25 faces backside surface protecting electrode 24 provided in contact with drain electrode 20. By heating solder layer 25, metal layer 22 is fixed to backside surface protecting electrode 24 through solder layer 25. Metal layer 22 is formed so as to cover an entire surface of fourth main surface 20b of drain electrode 20. The thickness of metal layer 22 is greater than the thickness of silicon carbide semiconductor substrate 10 after the step of removing at least a portion of silicon carbide semiconductor substrate 10 on a side of second main surface 10b.

According to the method for manufacturing silicon carbide semiconductor device 1 in accordance with the fourth embodiment, the step of forming metal layer 22 includes the step of forming metal layer 22 so as to cover an entire surface of fourth main surface 20b of drain electrode 20. Accordingly, on-resistance of silicon carbide semiconductor device 1 can be reduced effectively.

Moreover, according to the method for manufacturing silicon carbide semiconductor device 1 in accordance with the fourth embodiment, the step of removing at least a portion of silicon carbide semiconductor substrate 10 on a side of second main surface 10b includes the step of entirely removing silicon carbide single-crystal substrate 11 so that silicon carbide epitaxial layer 32 is exposed. Accordingly, on-resistance of silicon carbide semiconductor device 1 can be reduced more effectively.

According to silicon carbide semiconductor device 1 in accordance with the fourth embodiment, metal layer 22 is provided so as to cover an entire surface of fourth main surface 20b of drain electrode 20. Accordingly, on-resistance of silicon carbide semiconductor device 1 can be reduced effectively.

It should be noted that, each of the above-described embodiments, MOSFET 1 having the configuration in which the n-type and p-type are switched may be used. Moreover, although MOSFET 1 of a planar type is described as one example of silicon carbide semiconductor device 1 in accordance with the present invention in the description above, silicon carbide semiconductor device 1 may be a trench-type MOSFET 1, IGBT (Insulated Gate Bipolar Transistor), a Schottky barrier diode, or the like.

It should be understood that the embodiments disclosed herein are illustrative and non-restrictive in every respect. The scope of the present invention is defined by the scope of the claims, rather than the description above, and is intended to include any modifications within the scope and meaning equivalent to the scope of the claims.

### REFERENCE SIGNS LIST

1 silicon carbide semiconductor device (MOSFET); 4 JTE region; 5 girdling region; 6 field stop region; 10 silicon carbide semiconductor substrate; 10a first main surface; 10b second main surface; 10c outer circumferential end portion; 11 silicon carbide single-crystal substrate; 11a side wall portion; 11b base portion; 12 drift region; 13 body region; 14 source region; 15 insulating film; 15a gate insulating film; 15c breakdown voltage holding portion; 16 first electrode (source electrode); 18 contact region; 19 source interconnection; 20 second electrode (drain electrode); 20a third main surface; 20b fourth main surface; 21 interlayer insulating film; 22 metal layer; 23, 24 backside surface protecting electrode; 25 solder layer; 27 gate electrode; 31 buffer layer; 32 silicon carbide epitaxial layer; A side wall surface; B bottom portion; DL dicing line; DP dicing portion; T1, T2, T3 thickness; TQ recess.

1. A method for manufacturing a silicon carbide semiconductor device, comprising the steps of:
preparing a silicon carbide semiconductor substrate having a first main surface and a second main surface opposite to the first main surface,
the silicon carbide semiconductor substrate including a silicon carbide single-crystal substrate constituting the second main surface and a silicon carbide epitaxial layer being provided in contact with the silicon carbide single-crystal substrate and constituting the first main surface;
forming a first electrode being in contact with the first main surface of the silicon carbide semiconductor substrate and in ohmic junction with the silicon carbide semiconductor substrate;
removing at least a portion of the silicon carbide semiconductor substrate on a side of the second main surface;
forming a second electrode having a third main surface, which is in contact with the second main surface of the silicon carbide semiconductor substrate exposed by the step of removing at least a portion of the silicon carbide semiconductor substrate on a side of the second main surface, and a fourth main surface opposite to the third main surface, and in ohmic junction with the silicon carbide semiconductor substrate; and
forming a metal layer being in electrical contact with the fourth main surface of the second electrode,
a thickness of the metal layer being greater than a thickness of the silicon carbide semiconductor substrate after the step of removing at least a portion of the silicon carbide semiconductor substrate on a side of the second main surface.

2. The method for manufacturing a silicon carbide semiconductor device according to claim 1, wherein the step of forming a metal layer includes the step of forming the metal layer so as to cover an entire surface of the fourth main surface of the second electrode.

3. The method for manufacturing a silicon carbide semiconductor device according to claim 1 or 2, wherein the step of removing at least a portion of the silicon carbide semiconductor substrate on a side of the second main surface includes the step of entirely removing the silicon carbide single-crystal substrate so that the silicon carbide epitaxial layer is exposed.

4. The method for manufacturing a silicon carbide semiconductor device according to claim 1, wherein
the step of removing at least a portion of the silicon carbide semiconductor substrate on a side of the second main surface includes the step of forming a recess in the second main surface of the silicon carbide semiconductor substrate, and
the step of forming a metal layer includes the step of forming the metal layer which enters the recess and covers the second main surface, and
the method further comprises the step of removing a portion of the metal layer by chemical machine polishing so that the second main surface of the silicon carbide semiconductor substrate is exposed after the step of forming a metal layer.

5. The method for manufacturing a silicon carbide semiconductor device according to claim 4, wherein the step of forming a recess in the second main surface of the silicon carbide semiconductor substrate has the step of forming the recess so that the silicon carbide single-crystal substrate remains along a dicing line.

6. The method for manufacturing a silicon carbide semiconductor device according to claim 4 or 5, wherein the step of forming a recess in the second main surface of the silicon carbide semiconductor substrate has the step of forming the recess so that a bottom portion of the recess is located in the silicon carbide epitaxial layer.

7. The method for manufacturing a silicon carbide semiconductor device according to claim 1, wherein a thickness of a portion removed by the step of removing at least a portion of the silicon carbide semiconductor substrate on a side of the second main surface is greater than or equal to 250 μm and less than or equal to 500 μm.

8. The method for manufacturing a silicon carbide semiconductor device according to claim 1, wherein a thickness of the metal layer is greater than or equal to 50 μm and less than or equal to 300 μm.

9. A silicon carbide semiconductor device comprising:
a silicon carbide semiconductor substrate having a first main surface and a second main surface opposite to the first main surface,
the silicon carbide semiconductor substrate including a silicon carbide epitaxial layer constituting the first main surface;
a first electrode being in contact with the first main surface of the silicon carbide semiconductor substrate and in ohmic junction with the silicon carbide semiconductor substrate;
a second electrode having a third main surface in contact with the second main surface of the silicon carbide semiconductor substrate and a fourth main surface opposite to the third main surface, and in ohmic junction with the silicon carbide semiconductor substrate; and
a metal layer being in electrical contact with the fourth main surface of the second electrode,
a thickness of the metal layer being greater than a thickness of the silicon carbide semiconductor substrate.

10. The silicon carbide semiconductor device according to claim 9, wherein the metal layer is provided so as to cover an entire surface of the fourth main surface of the second electrode.

11. The silicon carbide semiconductor device according to claim 9, wherein the silicon carbide semiconductor substrate includes a silicon carbide single-crystal substrate being in contact with the silicon carbide epitaxial layer and constituting the second main surface.

12. The silicon carbide semiconductor device according to claim 11, wherein
the second main surface of the silicon carbide semiconductor substrate is provided with a recess having a side wall portion constituted of the silicon carbide single-crystal substrate, and
the second electrode and the metal layer are provided so as to enter the recess.

13. The silicon carbide semiconductor device according to claim 12, wherein the recess is formed so that the silicon carbide single-crystal substrate remains in an outer circumferential end portion of the silicon carbide semiconductor substrate in a plan view.

14. The silicon carbide semiconductor device according to claim 12, wherein a bottom portion of the recess is located in the silicon carbide epitaxial layer.

15. The silicon carbide semiconductor device according to claim 9, wherein a thickness of the metal layer is greater than or equal to 50 μm and less than or equal to 300 μm.

16. The silicon carbide semiconductor device according to claim 9, wherein the metal layer contains copper.
